(19) United States
(12) Patent Application Publication
(10) Pub. No.: US 2006/0056547 A1
(43) Pub. Date: Mar. 16, 2006

(54) Analog/digital conversion with adjustable thresholds

(75) Inventors: Fred Buchali, Waiblingen (DE); Henning Bulow, Kornwestheim (DE); Bernd Franz, Brackenheim (DE)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/218,649

(22) Filed: Sep. 6, 2005

(30) Foreign Application Priority Data
Sep. 7, 2004 (EP) 04292152.8

(51) Int. Cl. H03D 1/00

(52) U.S. Cl. 375/341

(57) ABSTRACT

A device for receiving a distorted signal, in particular an optical signal converted by an opto/electrical converter, comprises an analog/digital converter (1) with adjustable thresholds and a Viterbi equalizer (10). The device further comprises a histogram estimator (13) for determining a probability density function of the distorted signal and a threshold estimator (4) for dynamically adjusting at least one threshold of the analog/digital converter (1) in an overlap region of a first signal amplitude attributed to a first symbol (σ₁₀, X₁₀) and a second signal amplitude attributed to a second symbol (σ₁₁, X₁₁) of the probability density function.

### The invention is based on a priority application EP 04292152.8 which is hereby incorporated by reference,

### BACKGROUND OF THE INVENTION

The invention relates to a device for receiving a distorted signal, in particular an optical signal converted by an opto/electrical converter, comprising an analog/digital converter with adjustable thresholds and a Viterbi equalizer.

Digital optical signals traversing an optical fiber link are subject to distortion and noise which may produce bit errors at the receiver side. At higher transmission rates or longer span lengths, error correction may thus be performed at the receiver side to reduce the error rate of distorted signals. A known method of error correction, the Maximum Likelihood Sequence Estimation (MLSE) reducing errors caused by inter-symbol interference (ISI), uses a Viterbi equalizer. Viterbi equalizers require analog to digital conversion of received optical signals after signal detection in a photodiode.

Most analog to digital converters (ADC) follow a linear scale, i.e. the scale for a given bit resolution is subdivided in equidistant steps per bit. Optical noise, however, is signal dependent and therefore the optimum characteristic of the analog-to-digital converter (ADC) is not necessarily linear.

High speed ADC of 10-40 Gb/s data signals suffer from technological constraints. Therefore only 3 bit or 4 bit resolution can be used. On the other hand, in particular with low noise and distortions, i.e. at a low bit-error-ratio, a small number of thresholds can result in a significant higher bit-error-ratio. This results in only roughly estimated channel parameters and therefore not optimum operation.

U.S. Pat. No. 6,417,965 discloses an optical amplifier control system that uses a non-linear analog-to-digital converter with a logarithmic scale but does not show an implementation of such an ADC.

### OBJECT OF THE INVENTION

It is the object of the invention to provide a device of the above-mentioned kind in which for a given number of thresholds a bit-error-ratio is minimized.

### BRIEF DESCRIPTION OF THE INVENTION

This object is achieved by a device which comprises a histogram estimator for determining a probability density function of the distorted signal and a threshold estimator for dynamically adjusting at least one threshold of the analog/digital converter in an overlap region of a first signal amplitude attributed to a first symbol and a second signal amplitude attributed to a second symbol of the probability density function.

Symbols are defined by a number of channel parameters. Among these, the expected values and their standard deviation are the most relevant.

The above adaptation of ADC threshold levels sets these levels to relevant points in the voltage distribution of the distorted electrical signal, such that an optimized analog/digital conversion for further signal processing is possible. The invention is particularly suited for low resolution ADC (3-4 bit) and may be applied to receivers in systems with significant signal distortion which has to be mitigated and in systems which are operated close to noise limit.

In a preferred embodiment, the threshold is set at an intersection point of the first signal amplitude attributed to the first symbol and the second signal amplitude attributed to the second symbol. Intersection points of overlapping symbols are relevant points of the probability density function.

In a further preferred embodiment, the threshold is set such that a ratio of symbol counts in a first quantization stage is equal to a reciprocal ratio of symbol counts in a second, adjacent quantization stage, wherein the ratio of symbol counts in the first quantization stage is defined by a quotient of a number of bit counts attributed to the first symbol and a number of bit counts attributed to the second symbol. By using the above relation for fixing the threshold, an alternative way for determining relevant points of the distribution is provided.

In a preferred embodiment, the overlap region where the threshold is set is chosen in dependence of a bit error ratio of a forward error correction. In this way, those points in the probability density function which are most suited for placing threshold levels can be easily determined.

In a further preferred embodiment, a lower threshold is set in a first overlap region, an upper threshold is set in a second overlap region, a first supplementary threshold is set below the lower threshold, a second supplementary threshold is set above the upper threshold, and the remaining thresholds are set in between the lower threshold and the upper threshold. The upper and lower thresholds limit the range in which the quantization stages of the analog/digital converter are set. This range can be considerably smaller than the overall dynamic range of the analog/digital converter and of the data signal.

In a preferred embodiment, the histogram estimator comprises a comparator for determining a cumulative voltage distribution of the distorted signal by comparing the distorted signal with a varying threshold signal. In this way, the cumulative voltage distribution can be easily obtained. The probability density function can be determined by derivation of the cumulative voltage distribution after averaging.

In a further preferred embodiment the threshold signal is a finely quantized saw-tooth voltage generated in a counter and converted to an analog signal by a digital/analog converter. The finely quantized saw-tooth voltage covers the whole dynamic range of the ADC.

In another preferred embodiment, the histogram estimator comprises an averaging means for averaging the cumulative density function of the distorted signal. The averaging can be achieved by using a low-pass filter.

In a further preferred embodiment, the histogram estimator comprises a voltage histogram determination means for determining the probability density function as a derivative of the averaged cumulative density function. The probability density function, also called voltage histogram, yields the probability density of voltage values over the dynamic range of the analog/digital converter. Knowledge of this distribution allows to determine relevant regions of the distorted signal.

In another preferred embodiment, a parameter estimation means for estimating channel parameters of the Viterbi equalizer is provided. The parameter estimation means uses the probability density function for the determination of the channel parameters of the Viterbi equalizer. Precisely estimated channel parameters are crucial to ensure a low bit-error-ratio of the Viterbi equalizer.

Further advantages may be extracted from the description and the enclosed drawings. The features mentioned above and below may be used in accordance with the invention either individually or collectively in any combination. The embodiments mentioned are not to be understood as an exhaustive enumeration but rather have an exemplary character for the description of the invention.

### DRAWINGS

The invention is shown in the drawings, wherein:

FIG. 1 shows a circuit diagram of a device according to the invention,

FIG. 2 shows a circuit diagram of a state-of-the art analog/digital converter,

FIG. 3 shows three signal amplitudes attributed to three symbols with two overlap regions and five threshold levels,

FIG. 4 shows a comparator output signal in dependence of the voltage of a distorted signal and a finely quantized saw-tooth voltage,

FIG. 5 shows a cumulative distribution function of the voltage of the distorted signal after averaging, and

FIG. 6 shows a probability density function of the distorted signal after building the histogram.

### DESCRIPTION OF PREFERRED EMBODIMENTS

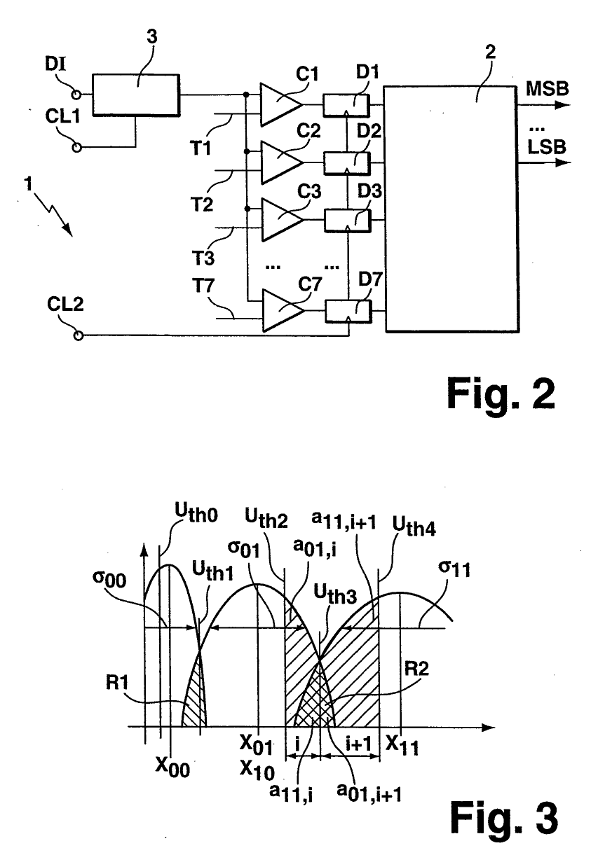

FIG. 2 shows a state-of-the-art analog/digital converter 1 with three bit conversion. The analog signal to be converted is applied to a signal input D1. A sample-and-hold (S&H) circuit 3 samples the analog value and holds it for one clock period of a clock signal input CL1 (clock related issues are not shown in the circuit diagram but would be apparent to and could thus easily be added by those skilled in the art). The sampled value is then compared to external threshold values from threshold inputs T1 through T7 in comparators C1 through C7 which are arranged in parallel. Output signals of the compensators C1 through C7 are then used as an input to D-flip-flops D1 through D7 which are connected to a common clock input CL2. Output signals of the D-flip-flops D1 through D7 are used as input signals for a linear to binary encoder 2 which creates a three-bit digital output signal.

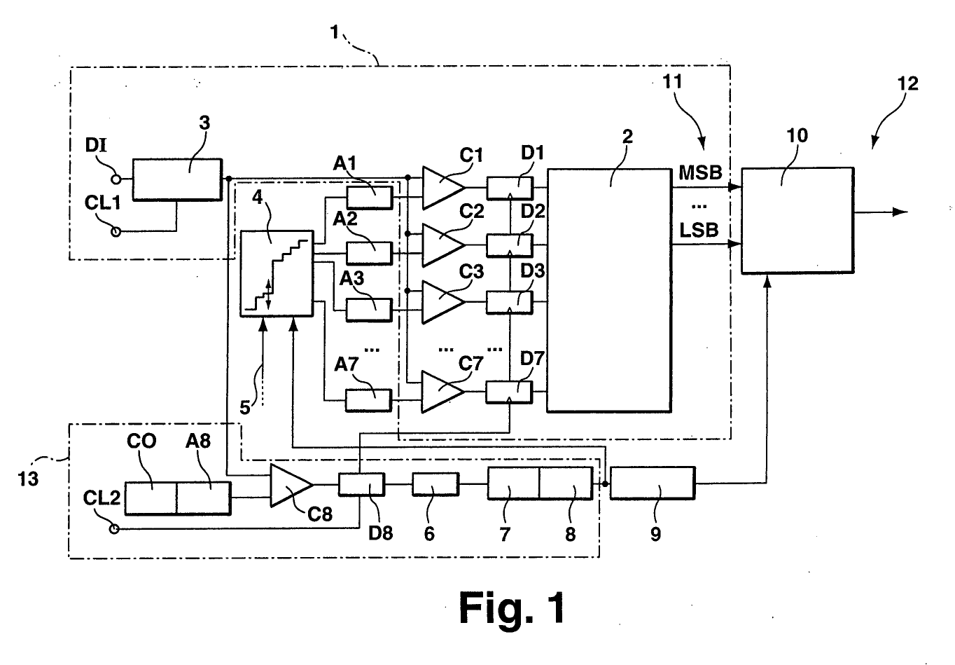

FIG. 1 shows the state-of the-art analog/digital converter 1 of FIG. 2 as part of a device which comprises some additional components for the fixation of threshold levels, in particular a threshold estimator 4 and a histogram estimator 13. The threshold estimator 4 fixes digital values for threshold levels. These digital values are converted to analog signals in digital/analog converters A1 through A7 and are used as threshold inputs for the comparators C1 through C7.

The threshold estimator 4 is provided with the probability density function of the distorted signal of the signal input DI. Thresholds are adapted in such a way that a bit-error-ratio of a subsequent Viterbi equalizer 10 is optimized, as described below. The Viterbi equalizer 10 receives a first digital bit signal 11 from the analog/digital converter 1 as an input and provides an equalized digital one-bit signal 12 as an output.

For determining the regions of the probability density function in which thresholds are most advantageously set, the threshold estimator 4 is provided with a connection means 5 for being connected to a forward error correction means (FEC, not shown). The bit-error ratio of the FEC can be used to identify relevant voltage values of the probability density function.

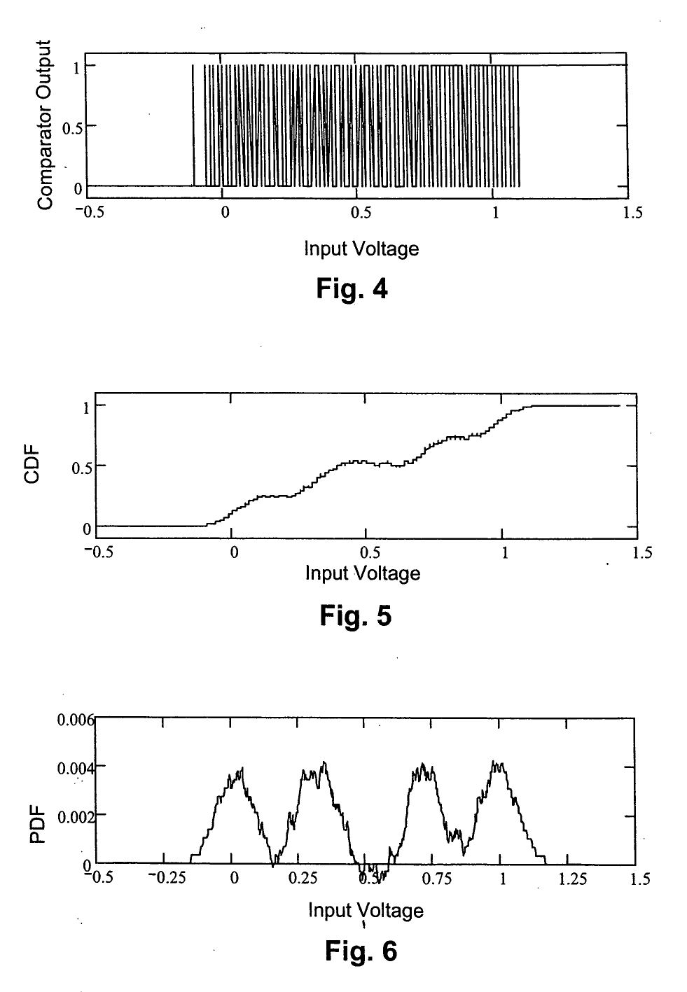

In order to obtain the probability density function, the input signal from the sample-and-hold circuit 3 is compared with a varying threshold signal in a comparator C8 of the histogram estimator 13. The varying threshold signal, a finely quantized saw-tooth voltage, is generated in a counter CO and converted into an analog signal in a digital/analog converter A8. For a noisy polarization mode distorted input data signal with Γ=0.3, the output signal of the converter C8 is shown in FIG. 4.

Since the statistics of the input signal is only slowly varying, the probability distribution function, i.e. the cumulative distribution function, can be obtained by averaging the output signal of C8. Therefore, after passing through a D-flip-flop D8, the signal is averaged in a low-pass filter 6 and then passed on to a high-resolution analog/digital converter 7. Since the signal is averaged over a large number of data bits a low speed ADC 7 can be taken.

FIG. 5 shows the output signal of the ADC 7, namely the cumulative distribution function CDF of the distorted input signal determined with six bit resolution. The derivative of the CDF is the probability density function PDF. This function is obtained by differentiation of the CDF in a voltage histogram determination means 8, whose output signal, shown in FIG. 6, is used as an input signal to the threshold estimator 4. Further digital computation in the threshold estimator 4 delivers the ADC thresholds with high accuracy, as described below. Using the PDF of the averaged distorted signal, channel model parameters of the Viterbi equalizer 10 can be determined by a parameter estimation means 9 and provided as an input for the Viterbi equalizer 10.

In the example shown in FIG. 6, four peaks in the PDF can be identified corresponding to four symbols. For each peak, an expected value X and a standard deviation a of a symmetrical Gaussian-like distribution can be obtained. Of course, other approximating distributions such as exponential functions, may be used for attributing parts of the probability density function to specific symbols. For the sake of simplicity, only symmetrical distributions will be considered in the following, although optical preamplified signals have signal dependent noise contributions leading to a more noisy “1” compared to “0”. A further adaptation to unsymmetrical noise is therefore advantageous, but is a straightforward matter for those skilled in the art.

FIG. 3 shows a probability density function of the distorted signal of the data input DI with three symbols corresponding to bit combinations {0,0}, {0,1}, {1,0} and {1,1}. Two of these bit combinations, namely {0,1} and {1,0}, are combined to constitute a first symbol.

The first symbol is defined by a first expected value X₀₁ coinciding with X₁₀ and a standard deviation σ₁₀ coinciding with σ₀₁. A second and third symbol are defined by an expectation value of X₁₁ resp. X₀₀ and a standard deviation σ₁₁ resp. σ₀₀. The first and the second symbol overlap in a second region R2. The first and the third symbol overlap in a first region R1.

In the threshold estimator 4, an upper threshold Uₜₕ₃ is set in the second region R2 at an intersection point of the first symbol with the second symbol. A lower threshold Uₜₕ₁ is set at an intersection point of the first symbol with the third symbol. A first supplementary threshold Uₜₕ₀ is set below the lower threshold Uₜₕ₁ and a second supplementary threshold Uₜₕ₄ is set above the upper threshold Uₜₕ₃. The remaining number of thresholds of the analog/digital converter 1 is set in between the lower threshold Uth, and the upper threshold Uₜₕ₃, as this region is identified to be the most relevant part of the dynamic range of the analog/digital converter 1. Therefore a high number of threshold levels is placed between the upper and the lower thresholds Uₜₕ₁ and Uₜₕ₃, of which only one threshold Uₜₕ₂ is exemplarily shown.

The thresholds between the lower and upper thresholds Uₜₕ₁ and Uₜₕ₃ may be set in equidistant stages. For more complicated power density functions with more than three symbols, some of the threshold levels between the upper and lower thresholds Uₜₕ₁ and Uₜₕ₃ may be fixed in the way described above.

The determination of threshold levels is possible by using intersection points of symbols. However, it is also possible to determine threshold levels with a procedure described in the following, exemplarily explained for the upper threshold level Uth₃. This method is advantageously applied in cases when intersection points are not known precisely, for example when channel parameters are not known with high accuracy.

The starting point of the method is to define a first quantization stage i and a second, adjacent quantization stage i+1 between which the threshold level Uₜₕ₃ has to be fixed. In the first stage i, a number of bit counts a_{01,i} attributed to the first symbol defined by channel parameters σ₀, X₀₁, represented in FIG. 3 as a hatched region in stage i between thresholds Uₜₕ₂ and Uₜₕ₃, and a number of bit counts a_{11,i} attributed to the second symbol defined by channel parameters σ₁₁, X₁₁ represented in FIG. 3 as a crosshatched region in stage i, are determined.

Likewise, a number of bit counts a_{01,i+1} attributed to the first symbol in stage i+1 and a number of bit counts a_{11,i+1} attributed to the second symbol in stage i+1 are determined. The upper threshold Uₜₕ₃ is determined in such a way that the following formula holds:
a_{01,i}/a_{11,i}=a_{11,i+1}/a_{01,i+1}.

The above formula may also be rewritten in the following form:
a_{01,i}·a_{01,i+1}=a_{11,i+1}·a_{11,i}.

The above reformulation makes clear that a threshold level between the first stage i and the second stage i+1 is set such that products of bit counts attributed to a specific symbol in the first stage i and the second stage i+1 are equal. It is to be understood that the upper threshold Uₜₕ₃ shown in FIG. 3 has only exemplary character and does not satisfy the above relation.

In summary, the invention makes available adapted threshold levels of an analog/digital converter and as well channel parameters of a Viterbi equalizer with high resolution. Evaluation of the voltage histogram of the input data signal with high resolution is possible. The adaptation of ADC threshold levels increases the resolution in significant amplitude regions, whereas non significant regions have reduced resolutions. Therefore, the invention increases performance of receivers with low resolution ADC.

1. Device for receiving a distorted signal, in particular an optical signal converted by an opto/electrical converter, comprising an analog/digital converter with adjustable thresholds and a Viterbi equalizer wherein the device comprises a histogram estimator for determining a probability density function of the distorted signal and a threshold estimator for dynamically adjusting at least one threshold of the analog/digital converter in an overlap region of a first signal amplitude attributed to a first symbol and a second signal amplitude attributed to a second symbol of the probability density function.

2. Device according to claim 1, wherein the threshold is set at an intersection point of the first signal amplitude attributed to the first symbol and the second signal amplitude attributed to the second symbol

3. Device according to claim 1, wherein the threshold is set such that a ratio of symbol counts in a first quantization stage is equal to a reciprocal ratio of symbol counts in a second, adjacent quantization stage, wherein the ratio of symbol counts in the first quantization stage is defined by a quotient of a number of bit counts attributed to the first symbol and a number of bit counts attributed to the second symbol.

4. Device according to claim 1, wherein the overlap region where the threshold is set is chosen in dependence of a bit error ratio of a forward error correction.

5. Device according to claim 1, wherein a lower threshold is set in a first overlap region, an upper threshold is set in a second overlap region, a first supplementary threshold is set below the lower threshold, a second supplementary threshold is set above the upper threshold and the remaining thresholds are set in between the lower threshold and the upper threshold.

6. Device according to claim 1, wherein the histogram estimator comprises a comparator for determining a cumulative voltage distribution of the distorted signal by comparing the distorted signal with a varying threshold signal.

7. Device according to claim 6, wherein the varying threshold signal is a finely quantized saw-tooth voltage generated in a counter and converted to an analog signal by a digital/analog converter.

8. Device according to claim 6, wherein the histogram estimator comprises an averaging means for averaging the cumulative density function of the distorted signal.

9. Device according to claim 8, wherein the histogram estimator comprises a voltage histogram determination means for determining the probability density function as a derivative of the averaged cumulative density function.

10. Device according to claim 1, wherein a parameter estimation means for estimating channel parameters of the Viterbi equalizer.
